(19) United States
(12) Patent Application Publication
(10) Pub. No.: US 2002/0167053 A1
(43) Pub. Date: Nov. 14, 2002

(54) Charge device model protection circuit

(76) Inventor: Shao-Chang Huang, Bu-Dai Chen (TW)

Correspondence Address: J.C. Patents, Suite 250, 4 Venture, Irvine, CA, 92618, US

(21) Appl. No.: 10/143,698

(22) Filed: May 8, 2002

Related U.S. Application Data
(63) Continuation-in-part of application No. 09/513,267, filed on Feb. 24, 2000, now abandoned.

(30) Foreign Application Priority Data
Jan. 14, 2000 (TW) 89100525

(51) Int. Cl. H01L 23/62; H01L 23/552

(52) U.S. Cl. 257/355; 257/360; 257/659

(57) ABSTRACT

A CDM protection is provided within an internal device region of an integrated circuit where a plurality of working components are formed. The CDM protection circuit comprises a plurality of CDM protection devices that are electrically connected to one another, and a grounded conductive pad electrically connected to one CDM protection device, the CDM protection devices including a plurality of dummy devices such as dummy metals in tapered shape. The CDM protection devices are distributed over the internal device region in a manner to achieve a global protection of the IC against CDM charges by absorbing and dissipating the CDM charges. To increase CDM protection, a capacitor is further disposed in a manner to surround the internal device region.

### CROSS-REFERENCE TO RELATED APPLICATION

Pursuant to 37 CFR 1.53(b), this is a continuation-in-part application of the parent application referenced Ser. No. 09/513,267, filed on Feb. 24, 2000.

### BACKGROUND OF THE INVENTION

1. Field of the Invention

The invention relates in general to a charge device model (CDM) protection circuit. More particularly, this invention relates to a CDM protection circuit that uses dummy devices that are formed along with the working components of an IC so that no additional specific design and fabrication process are needed to achieve the CDM protection circuit.

2. Description of the Related Art

In the fabrication process of integrated circuit (IC), the electrostatic discharge is the major problem that causes damage of the integrated circuit. During fabrication and testing of an IC, the electrostatic charges may be induced by the operator or generated by friction caused during conveyance. These electrostatic charges are accumulated to the operator or to the IC, or the operation ambient environment. Once the charges are in contact with the IC, occurs by human body model (HBM), charge device model (CDM) or machine model (NM), which damages [to damage] the IC.

Due to the high input impedance and the low breakdown voltage of a metal-oxide semiconductor field effect transistor (MOSFET), the strength to withstand the electrostatic discharge of the integrated circuits is poor. Electrostatic discharges most commonly electrically contact with the IC at the output port of the circuit. Therefore, an additional protection circuit is usually designed to provide a discharge path of the additional current caused during electrostatic discharge, thereby protecting the working devices of the IC from damages.

A CDM protection circuit is usually achieved by designing an internal protection circuit that is electrically coupled with the concerned working component of the IC to be protected. This type of protection circuit therefore only protects the working component connected thereto. The working components that are not coupled with any CDM protection circuits are therefore still vulnerable to damaging CDM charges. Ideally, a CDM protection circuit should be therefore coupled with any working components that need CDM protection, which would result in further design that additionally requires a substantial occupation space.

A traditional trade-off is therefore to dispose a CDM protection circuit where the IC is the most vulnerable to electrostatic discharges or where electrostatic discharge occurrences are the most probable. The CDM protection circuit of the prior art is therefore deficient to provide a global CDM protection within a reduced occupation space.

### SUMMARY OF THE INVENTION

It is therefore an object of the invention to provide a charge device model (CDM) protection circuit that can provide a global protection of an integrated circuit from CDM charges while necessitating a reduced occupation space.

To accomplish the above and other objectives, the invention provides a charge device model (CDM) protection circuit that is formed within an internal device region of an integrated circuit that includes a plurality of working components. The CDM protection circuit comprises a plurality of CDM protection devices and an external conductive pad. The protection devices are electrically connected to one another, and are preferably distributed over the internal device region of the integrated circuit in a manner to achieve a global protection by absorbing and dissipating CDM charges. At least one of the protection devices is further electrically connected to the pad. The pad is disposed outward the internal device region, and is preferably grounded. The conductive pad thus receives and discharges the CDM charges from the protection devices to protect the working components of the internal device region from being damaged by CDM charges. In addition, the protection circuit further comprises a capacitor that is disposed at a periphery of the internal device region and is electrically connected to the protection devices and the pad. This capacitor is used to dissipate the charges from the protection devices to the ground via the pad.

According to an embodiment of the invention, the CDM protection devices are dummy devices such as dummy metals in tapered shape. With CDM protection devices formed from dummy devices, the CDM protection circuit is economically achieved without the need of additional design and fabrication process. Moreover, the CDM protection circuit has a smaller occupation space on the internal device region.

According to another embodiment of the invention, the CDM protection devices are formed from transistors. The protection devices as transistors have their respective thin gate oxide connected to one another to facilitate a dissipation of CDM charges.

Both the foregoing general description and the following detailed description are exemplary and explanatory only and are not restrictive of the invention as claimed.

### BRIEF DESCRIPTION OF THE DRAWINGS

FIG. 1 is a schematic diagram illustrating a layout of a CDM protection circuit according to an embodiment of the invention;

FIG. 2 is a cross-sectional view of an embodiment of a CDM protection device as dummy device according to the invention;

FIG. 3 is a perspective view schematically illustrating a variant example of a CDM protection device as dummy device according to an embodiment of the invention; and

FIG. 4 is a cross-sectional view of another embodiment of a CDM protection device as transistor according to the invention.

### DESCRIPTION OF THE PREFERRED EMBODIMENTS

Reference now is made to the accompanying drawings to describe the specific embodiments and examples of the invention. For the sake of clear understanding, only the elements essential to the implementation of the invention are illustrated in the drawings, while other elements not concerned with the invention are omitted. Moreover, the drawings are strictly provided for an illustration purpose, and therefore are drawn generally not with a representation in scale.

To achieve a global CDM protection of an IC, the invention principally provides a CDM protection circuit that dissipates CDM charges by charge accumulation and dissipation mechanism. The CDM protection circuit comprises a plurality of CDM protection devices that are distributed over an internal device region among working components of the integrated circuit to protect those working components from CDM charges.

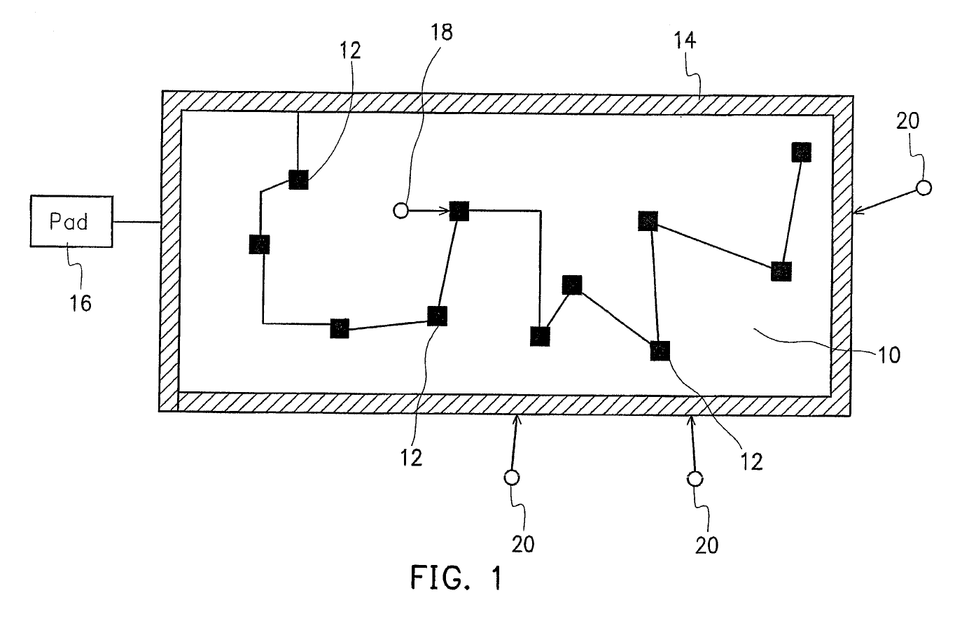

In FIG. 1, a layout of the CDM protection circuit according to an embodiment of the invention is illustrated. As illustrated, the dark squares within IC internal device region 10 represent CDM protection devices 12 that are distributed among working components of the IC (not shown). The protection devices 12 may be distributed either uniformly within the internal device region 10 to ensure a global protection, or according to a circuit density distribution within the internal device region 10. A capacitor 14 is formed at a periphery of the internal device region 10 to form a guard ring type dissipation structure. While the ringed capacitor 14 is formed in a manner to substantially enclose the internal device region 10, the protection devices 12 are further electrically connected to a conductive pad 16. The pad 16 may be also electrically connected to the capacitor 14.

The protection devices 12 are preferably comprised of dummy devices (as detailed hereafter) that are electrically connected together. Alternatively, the protection devices 12 can be, for example, NMOS or PMOS transistors that are purposedly formed to achieve the CDM protection circuit. Furthermore, the pad 16 is preferably located at a corner or a position that is easily subjected to CDM charges. If allowed by the circuit layout of the integrated circuit, the pad 16 is further preferably electrically connected to a ground voltage VSS to dissipate electrical charges.

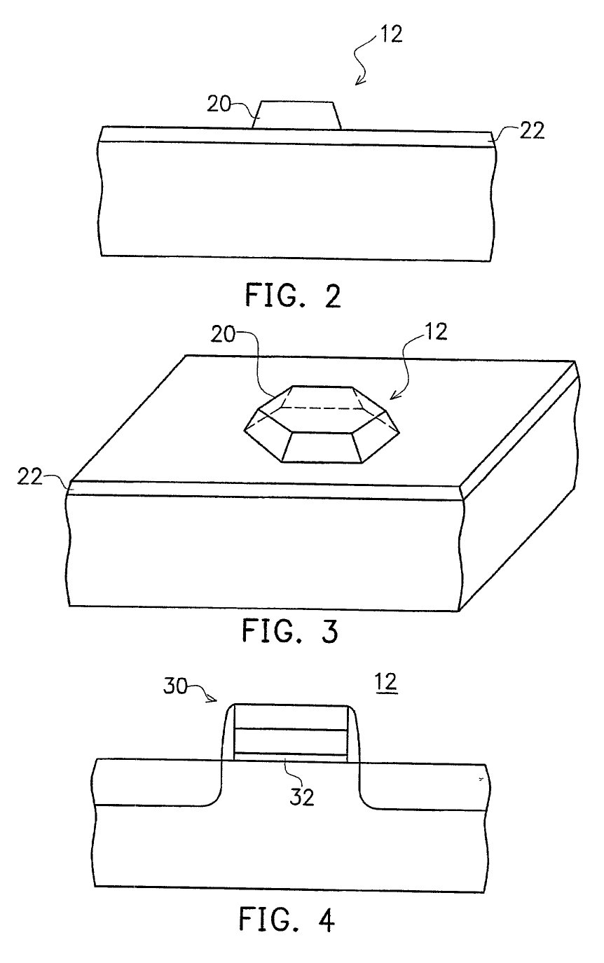

FIG. 2 and FIG. 3 illustrate preferred embodiments of protection device 12 as dummy device according to the invention. By “dummy device”, it is meant elements that are formed in the fabrication process along with the functional (working) components of the IC, but that may be removed once the circuitry of the IC is achieved because they are not elements necessary to the operations of the IC. In the present embodiment of the invention, those dummy devices are favorably used as protection devices so that no additional design and fabrication process are needed to achieve the CDM protection circuit. Such a dummy device may be, for example, comprised of a dummy metal 20 formed on an insulating layer 22 as illustrated in FIG. 2. The dummy metal 20 is preferably formed with a tapered shape so as to increase the attraction of electrical charges. The tapered dummy metal 20 may have a transversal section rectangular as illustrated in FIG. 1. However, in order to promote the formation of a tapered shape, a polygonal transversal section with a higher number of sides (composing the sidewalls of the dummy metal) may be also envisaged, as illustrated in FIG. 3. By increasing the number of sidewalls of the dummy metal 20 to be formed, the etching achieved to form the dummy metal is less uniform, which increases the occurrence of inclined sidewalls forming the tapered shape. The electrical connection as illustrated in FIG. 1 may be achieved by simply forming conductive wires. As dummy devices, the protection devices are grounded via either an electrical connection to a grounded pad 16 as illustrated in FIG. 1, or an individual ground connection achieved with respect to each dummy device.

Besides dummy device as described above, it should be understood that a protection device 12 may be also comprised of a CDM dissipating element specifically formed to achieve the CDM protection circuit, such as typical dissipating transistor 30 illustrated in FIG. 4. To achieve the CDM protection circuit, the protection devices 12, respectively formed as a NMOS or PMOS transistor 30, have their thin gate oxide 32 connected together. A relatively thinner gate oxide 32 facilitates the dissipation of CDM charges through the transistor 18.

When CDM charges 18 contact with the IC due to, for example, a friction action or a contact with a CDM charges source, the CDM charges 18 are absorbed and dissipated through the protection devices 12 and the pad 16 to the ground. To ensure that the CDM charges are dissipated to the ground, it is therefore preferable that the pad 16 is permanently electrically connected to a ground. By further providing the capacitor 14, a guard ring type protection circuit can be further constituted to dissipate CDM charges 18. As a result, working components of the IC can be effectively protected against CDM charges.

If the protection devices 12 are formed as grounded dummy devices, the CDM charges 18 may be dissipated by burning of those dummy devices, which prevents the damage of the components of the IC by CDM charges 18.

During a transportation of the IC, even if the pad 16 is not grounded, the CDM charges 18 that may be produced would accumulate in the CDM protection circuit and first damage either the oxide layers (included in protection devices 12 as transistors elements) or dummy devices of the protection devices 12. The CDM charges 18 also may be stored in the capacitor 14. Thereby, a substantial amount of CDM charges 18 may be absorbed and dissipated and damages of the working components of the IC can be prevented.

By providing an adequate distribution of the CDM protection circuit as described above, a global protection of the IC against CDM charges thus can be favorably achieved.

The invention as described above therefore includes at least the following advantages:

1. By providing a CDM protection circuit which protection devices may be comprised of dummy devices that have a small occupation space, the required surface area for forming the CDM protection circuit is therefore favorably reduced.

2. This reduction in surface area can be used for other circuit design.

3. When dummy devices are used within the CDM protection circuit, no additional design and process are needed to form the CDM protection circuit. Therefore, the CDM protection circuit of the invention is economical.

4. If necessary, a capacitor is formed around the IC to absorb the ambient CDM charges, thereby preventing an interference caused by external charges. In addition, the capacitor also provides an additional path for dissipating the CDM charges generated.

Other embodiments of the invention will be readily understood by those skilled in the art from consideration of the specification and practice of the invention as disclosed herein. It is intended that the specification and examples to be considered as exemplary only, with a true scope and spirit of the invention being indicated by the following claims.

What is claimed is:

1. A charge device model (CDM) protection circuit installed within an internal device region of an integrated circuit that has a plurality of working components, comprising:
a plurality of CDM protection devices, electrically connected to one another, the CDM protection devices being distributed over the internal region of the IC in a manner to achieve a global protection against damages due to CDM charges; and
an external pad, electrically connected to one of the CDM protection devices to receive and dissipate charge device model charges from the CDM protection devices.

2. The protection circuit according to claim 1, further comprising a capacitor disposed at a periphery of the internal device region and electrically connected to the CDM protection devices and the external pad.

3. The protection circuit according to claim 1, wherein the external pad is grounded.

4. The protection circuit according to claim 1, wherein the CDM protection devices are comprised of transistors respectively having a thin oxide layer.

5. A charge device model (CDM) protection circuit installed within an internal device region of an integrated circuit that has a plurality of working components, comprising:
a plurality of CDM protection devices comprised of a plurality of dummy devices, located in the internal device region, the CDM protection devices being electrically connected to one another to absorb and dissipate charge device model charges; and
a conductive pad, connected to one of the CDM protection devices to dissipate the charge device model charges, thereby preventing CDM damages of the working components.

6. The protection circuit according to claim 5, further comprising a capacitor disposed in a manner to surround a periphery of the internal device region, the capacitor being electrically connected to the CDM protection devices and the conductive pad.

7. The protection circuit according to claim 5, wherein the conductive pad is grounded.

8. The protection circuit according to claim 5, wherein the dummy devices include dummy metals that are formed in tapered shape.

9. A charge device model (CDM) protection circuit installed within an internal device region of an integrated circuit that has a plurality of working components, comprising:
a plurality of CDM protection devices formed as dummy metals, located in the internal device region, the dummy metals being electrically connected to one another to absorb and dissipate charge device model charges to a ground; and
a conductive pad, electrically connected to one of the dummy metals to dissipate the charge device model charges, thereby preventing CDM damages of the working components.

10. The protection circuit according to claim 9, wherein the dummy metals are formed in a tapered shape.

11. The protection circuit according to claim 9, further comprising a capacitor disposed in a manner to surround a periphery of the internal device region, the capacitor being electrically connected to the CDM protection devices and the conductive pad.

12. The protection circuit according to claim 9, wherein the conductive pad is grounded.
